(19) United States
(12) Patent Application Publication
(10) Pub. No.: US 2013/0134974 A1
(43) Pub. Date: May 30, 2013

(54) COMBINATION OF MR MEASUREMENT SIGNALS IN ORDER TO IMPROVE THE SIGNAL-TO-NOISE RATIO

(71) Applicant: Oliver Heid, Erlangen (DE)

(72) Inventor: Oliver Heid, Erlangen (DE)

(21) Appl. No.: 13/812,806

(22) PCT Filed: Jun. 28, 2011
(86) PCT No.: PCT/EP11/60757

§ 371 Date: Jan. 28, 2013

(30) Foreign Application Priority Data
Jul. 28, 2010 (DE) 10 2010 032 450.7

(51) Int. Cl. G06F 17/10; G01R 33/36

(52) U.S. Cl. CPC G06F 17/10; G01R 33/36
USPC 324/309; 324/322

(57) ABSTRACT

In a computerized method, a magnetic resonance system, and a data storage medium encoded with programming instructions, n magnetic resonance (MR) signals are provided to a processor and, in the processor, a combination of the n associated MR signals is formed by calculating a median of the n associated MR signals, as an ideal MR signal. The ideal MR signal is then either stored or used for further processing.

### BACKGROUND OF THE INVENTION

1. Field of the Invention

The invention concerns a method to evaluate MR measurement signals, and an electronically readable data storage medium, a processing device, and a magnetic resonance system for implementing such a method.

2. Description of the Prior Art

Magnetic resonance technique (MR) is a known modality with which images of the inside of an examination subject can be generated. Expressed in a simplified manner, for this purpose the examination subject is positioned in a strong, static, homogeneous basic magnetic field BO (field strengths from 0.2 Tesla to 7 Tesla or more) in a magnetic resonance apparatus so that nuclear spins in the subject orient along the basic magnetic field. For spatial coding of the measurement data, rapidly switched magnetic gradient fields are superimposed on the basic magnetic field. To trigger nuclear magnetic resonances, radio-frequency excitation pulses (RF pulses) are radiated into the examination subject by a transmission coil; the triggered nuclear magnetic resonances (signals) are measured by reception coils; and anatomical MR images (for example) are reconstructed on the basis of the measured signals. The magnetic flux density of these RF pulses is typically designated with B1. The pulse-like radio-frequency field is therefore generally also called a B1 field. The nuclear spins of the atoms in the examination subject are thereby excited by these radio-frequency pulses such that they are deflected out of their rest state (parallel to the basic magnetic field B1) by an amount known as an “excitation flip angle” (also abbreviated as a “flip angle” in the following). The nuclear spins then precess around the direction of the basic magnetic field B0. The magnetic resonance signals that are thereby generated are received by radio-frequency reception antennas. The measurement signals that are thus acquired are digitized and stored in a k-space matrix as complex numerical values (also called raw data). Through multidimensional Fourier transformation of the values (entries) of the k-space matrix, the measurement signals can be converted into image data (for example) in order to reconstruct an associated MR image from the k-space matrix populated with values. In addition to anatomical images, spectroscopy data, movement data or temperature data of an examined or treated area can be determined by magnetic resonance techniques.

In the evaluation of MR measurement signals, sufficiently many signals are typically acquired in order to be able, for example, to calculate arithmetic sums and mean values to improve the signal-to-noise ratio (SNR), and thus to be able to compensate for errors in the measurement data. Errors frequently occur due to the high sensitivity of the signal acquisition and (for example) outliers occurring via RF interferences in the signals.

### SUMMARY OF THE INVENTION

An object of the present invention to provide a method to evaluate MR measurement signals in which a stable evaluation is enabled with regard to outliers, as well as to provide a magnetic resonance apparatus and a non-transitory, computer-readable data storage medium encoded with programming instructions to implement such a method.

A method according to the invention for the evaluation of MR measurement signals includes a combination of n associated MR measurement signals, wherein the combination of MR measurement signals includes the calculation of a median of the n MR measurement signals to determine an ideal MR measurement signal.

A determination of a middle value as the median has the advantage that the determination is insensitive with regard to a series of values that is not Gaussian-distributed, i.e. a series that includes aberrant values known as “outliers”. The “outliers” are not taken into account in the determination of the median. Furthermore, as a result of this determination, an operating expenditure (connected with high costs) in the actual data acquisition in order to avoid such outliers from being acquired can at least be reduced.

The present invention also encompasses a non-transitory, computer-readable data storage medium encoded with programming instructions that, when the storage medium is loaded into a computerized control and evaluation system of a medical imaging apparatus, such as a magnetic resonance imaging apparatus, cause the imaging apparatus to implement any or all of the above-described embodiments of the method according to the invention.

A processing device according to the invention is designed or configured to implement the above method.

A magnetic resonance system according to the invention has a processing device that is designed or configured to implement the above method.

The advantages and embodiments cited with regard to the method analogously apply to the electronically readable data storage medium, the processing device and the magnetic resonance system.

### BRIEF DESCRIPTION OF THE DRAWINGS

FIG. 1 schematically illustrates a magnetic resonance apparatus in accordance with the invention that is operable to implement the method in accordance with the invention.

FIG. 2 is a schematic flowchart of an embodiment of the method according to the invention.

### DESCRIPTION OF THE PREFERRED EMBODIMENTS

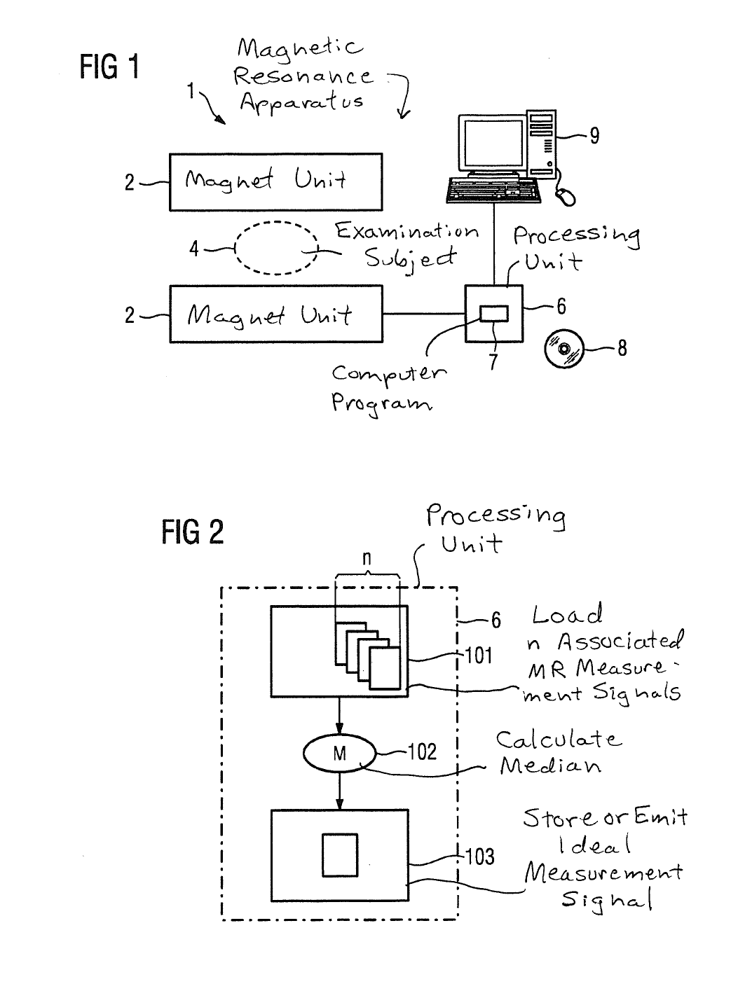

A magnetic resonance apparatus 1 is shown in FIG. 1. The magnetic resonance apparatus 1 has a magnetic resonance that is represented by its magnet unit 2. Additional components of the magnetic resonance data acquisition unit (such as gradient coil unit and RF units) as well as their interaction are known, and therefore are not shown for clarity.

In an MR examination, an examination subject is located in an examination subject 4 within the magnet unit 2 of the magnetic resonance data acquisition unit. As described above, during an MR examination RF pulses are radiated into the examination subject, and MR measurement signals resulting from this are measured. The measured MR measurement signals are transferred to a processing unit 6 connected with the magnetic resonance data acquisition unit and are stored there, and are processed into image data, for example (possibly after a pre-processing).

Furthermore, the processing unit 6 is connected with an input/output unit 9 that receives data from the processing unit 6 and can present image data (for example) to a user, and can send data input by a user (for example control commands for the acquisition of MR measurement signals with the magnetic resonance apparatus 1 or for processing of already measured MR measurement signals) to the processing unit 6.

When programming instructions forming a computer program 7 according to the invention are loaded into the programmable processing unit 6 of the magnetic resonance apparatus 1, the subsequently described method can be executed when the instructions included in the computer program product 7 are executed at the processing unit 6. The programming instructions forming the computer program 7 can be stored as electronically readable control information on an electronically readable data storage medium 8, and thus enable an implementation of the method given use of the data medium 8 in the processing unit 6 of the magnetic resonance apparatus 1.

FIG. 2 schematically shows the workflow of a method according to the invention.

For this purpose, n associated MR measurement signals are loaded (101) into a processing unit 6 and evaluated, wherein the evaluation includes a combination of the n associated MR measurement signals (102). The combination of the n associated MR measurement signals includes the calculation of a median (M) of the n associated MR measurement signals to determine an ideal measurement signal. The result of the evaluation using the measurement signal determined as an ideal measurement signal is, for example, stored for additional processing or provided for an output to an output device 9 (103).

Associated MR measurement signals can be raw data, for example. For example, the ability to be associated is therefore due to the fact that the MR measurement signals were acquired at the same k-space position, or that otherwise the same condition is present, for example acquisition in the same slice or position of the examination subject or also an acquisition of the MR measurement signals at the same position within a periodic movement made by the examination subject during the acquisition of the MR measurement signals. In particular in the acquisition of MR measurement signals in connection with radiation therapy and/or isotope generators, a repeated acquisition of associated MR measurement signals and a determination of an ideal MR measurement signals from these associated MR measurement signals is normally to be implemented.

For example, an evaluation of the raw data can include a Fourier transformation in order to calculate image data or spectroscopic data from the raw data. Additionally or alternatively, the evaluation can include a pure calculation of a median or a multiple of the median in order to improve the SNR of the acquired MR measurement signals.

However, associated MR measurement signals can already be image data calculated from raw data. For example, the association capability is hereby due to the fact that the MR measurement signals are measurement signals of the same position of individual MR images or series of MR images of a slice of the examination subject.

For example, an evaluation of the image data can be a pure calculation of a median or a multiple of the median of the n image data, for example to intensify the contrast or to compensate for intensity differences or to improve the SNR.

Furthermore, the evaluation can additionally or alternatively be a correlation with a time function, for example in order to determine the same points in time within a periodically changing measurement condition.

In a type of MR imaging known as “functional imaging” (FI) MR measurements (by means of which brain activities can be visualized, for example) are implemented to generate an image series on the order of approximately 100 images or even more of the same position, in order to allow statistically significant conclusions about the acquired examination subject (the brain or parts of the brain). For example, a stimulation of the brain is made (for example at defined times during the acquisition of this image series), for example by a specific movement that the patient executes or a defined stimulus that is exerted on the patient. The acquired image series is then divided into two groups, for example. For example, this takes place via a correlation with a time function in which the acquisition times of the individual MR images of the image series are compared with the times at which the stimulation took place, or by other suitable means. One group thus includes the MR images of the series during which no stimulation occurred and another group of the series includes those MR images of the series during which a stimulation occurred. The MR images of the respective groups are then statistically examined in order to discover those brain regions in which an activity is to be determined during the stimulation. An activity of a specific region in the acquired examination subject is assumed when a statistically significant difference can be established in the MR images of the two cited groups. Corresponding image data of the series or, respectively, a group of the series are examined in the statistical examination. Corresponding image data in this sense are, for example, pixel intensities of the same respective position in the individual MR images of the series or, respectively, a group of the series.

Aforementioned evaluations with regard to raw data, and also with regard to image data, have previously for the most part been executed in prevalent methods using an arithmetic mean value or arithmetic sum to determine an ideal measurement signal, which leads to a large tendency towards error at “outliers” in the acquired MR measurement signals. Such series of measurement signals with outliers, which series are not Gaussian-distributed, are caused by (for example) occurring RF interferences or what are known as “spikes” (electric discharges at the gradient coils) that can only be avoided with difficulty, and therefore are frequently found in MR measurement signals.

In a median determination, a middle value is determined from a series of values sorted according to their size. A determination of a middle value via a median has the advantage that it is also insensitive to a series of values that are not Gaussian-distributed (i.e. series which include what are known as “outliers”). The “outliers” are namely not also taken into account in the determination of the median.

For example, the following types of a median of a series of MR measurement values (x₁, x₂, . . . , xₙ) are possible:

The “conventional” median:

$$\tilde{x} = \{ \begin{matrix}{x}_{\frac{n + 1}{2}} & for n odd \\ \frac{1}{2} ( {x}_{\frac{n}{2}} + {x}_{\frac{n}{2} + 1} ) & for n even ,\end{matrix}$$

The lower median:

$${\tilde{x}}_{U} = \{ \begin{matrix}{x}_{\frac{n + 1}{2}} & for n odd \\ {x}_{\frac{n}{2}} & for n even ,\end{matrix}$$

The upper median:

$${\tilde{x}}_{O} = \{ \begin{matrix}{x}_{\frac{n + 1}{2}} & for n odd \\ {x}_{\frac{n}{2} + 1} & for n even .\end{matrix}$$

The upper median and the lower are characterized in that the (upper or, respectively, lower) median determined as an ideal value is always a value of the original series, in contrast to which—given an even number of elements in the series given a “conventional” median—the mean value of the two values situated in the middle of the series is consequently determined as an ideal value.

By the use of a median instead of arithmetic mean values or a multiple of a median instead of arithmetic sums, a sufficiently high degree of robustness of the evaluation with regard to outliers can be achieved, so that the previous technical operating cost to avoid such outliers (for instance RF shielding cabinets or an optimally cavity-free casting of the gradient coils) can at least be reduced without reducing the stability of the information about the examination subject that can be obtained from the MR measurement signals. The high costs connected with the technical measures could thus likewise be reduced. An evaluation of the MR images according to the invention is in particular particularly robust for statistical evaluations of a number of MR images.

Although modifications and changes may be suggested by those skilled in the art, it is the intention of the inventor to embody within the patent warranted heron all changes and modifications as reasonably and properly come within the scope of his contribution to the art.

I claim as my invention:

1.-11. (canceled)

12. A method for computerized, automated evaluation of magnetic resonance (MR) measurement signals, comprising:
supplying n associated MR measurement signals to an input of a processor;
in said processor, combining the n associated MR measurement signals by calculating a medium of n associated MR measurement signals, as an ideal MR measurement signal; and
making said ideal MR measurement signal available in electronic form at an output of said processor.

13. A method as claimed in claim 12 comprising supplying said ideal MR measurement signal from said output of said processor to an electronic memory, and storing said ideal MR measurement signal in said electronic memory.

14. A method as claimed in claim 12 comprising calculating said median as a median selected from the group consisting of an upper median, a lower median, and a conventional median.

15. A method as claimed in claim 12 comprising providing image data to said input of said processor as said n associated MR measurement signals.

16. A method as claimed in claim 15 comprising providing said image data to said input of said processor as individual MR images or a series of MR images.

17. A method as claimed in claim 15 comprising providing said image data to said input of said processor as image data of a series of MR images.

18. A method as claimed in claim 17 comprising providing said image data to said input of said processor as image data of an associated group of MR images of a series of MR images.

19. A method as claimed in claim 18 comprising providing said image data to said input of said processor with said associated groups of MR images of said series of said MR images being differentiated by correlation with a time function.

20. A processing device comprising:
a processor unit comprising an input and an output;
said processor unit being configured to receive, at said input, n associated MR measurement signals to an input of a processor;
said processor unit being configured to combine the n associated MR measurement signals by calculating a medium of n associated MR measurement signals, as an ideal MR measurement signal; and
said processor unit being configured to make said ideal MR measurement signal available in electronic form at said output.

21. A magnetic resonance (MR) system comprising:
an MR data acquisition unit configured to operate to acquire small n associated MR measurement signals;
a processor comprising an input in communication with said MR data acquisition unit, to which said n associated MR measurement signals are supplied from said MR data acquisition unit;
said processor being configured to combine said n associated MR measurement signals by calculating a median of said n MR measurement signals, as an ideal measurement signal; and
said processor being configured to make said ideal MR measurement signal available at an output of said processor in electronic form.

22. A magnetic resonance system as claimed in claim 21 comprising a memory in communication with said output of said processor, and wherein said processor is configured to cause said ideal MR measurement signal to be stored in said memory.

23. A magnetic resonance system as claimed in claim 21 wherein said processor is a first processor, and comprising a second processor having an input in communication with said output of said first processor, said second processor being configured to post-process said ideal MR measurement signal.

24. A magnetic resonance system as claimed in claim 23 wherein said first processor and said second processor are combined as a single processing system.

25. A non-transitory, computer-readable data storage medium encoded with programming instructions, said data storage medium being loadable into a computerized processor and said programming instructions causing said processor to:
at an input of said processor, receive n associated magnetic resonance (MR) measurement signals;
form a combination of said n measurement signals by calculating a median of said n MR measurement signals, as an ideal MR measurement signal; and
make said ideal MR measurement signal available in electronic form at an out output of said processor.
